(19) United States
(12) Patent Application Publication
(10) Pub. No.: US 2025/0210307 A1
(43) Pub. Date: Jun. 26, 2025

(54) ETCHING METHOD AND PLASMA PROCESSING APPARATUS

(71) Applicant: Tokyo Electron Limited, Tokyo (JP)

(72) Inventors: Sho SAITOH, Miyagi (JP); Yoshimitsu KON, Miyagi (JP); Noriyuki SAKAYA, Miyagi (JP)

(73) Assignee: Tokyo Electron Limited, Tokyo (JP)

(21) Appl. No.: 19/074,475

(22) Filed: Mar. 10, 2025

Related U.S. Application Data
(63) Continuation of application No. PCT/JP2024/034244, filed on Sep. 25, 2024.

(30) Foreign Application Priority Data
Sep. 29, 2023 (JP) 2023-169435

(51) Int. Cl. H01J 37/32; H01L 21/311

(52) U.S. Cl. CPC H01J 37/32174; H01L 21/31116; H01J 2237/334

(57) ABSTRACT

An etching method includes: (a) providing a substrate, which includes a stacked film including a silicon oxide film and a silicon nitride film; (b) etching the silicon nitride film, while applying a first bias voltage to a substrate support configured to support the substrate, by using a first plasma generated from a first processing gas including a hydrofluorocarbon gas; and (c) etching the silicon oxide film, while applying a second bias voltage to the substrate support, by using a second plasma generated from a second processing gas including a fluorocarbon gas, an absolute value of a voltage value of the second bias voltage being larger than an absolute value of a voltage value of the first bias voltage, wherein each of the first bias voltage and the second bias voltage is a pulsed wave in which on and off states of a pulse of a DC voltage are repeated periodically.

### CROSS-REFERENCE TO RELATED APPLICATIONS

This application is a Bypass Continuation Application of PCT International Application No. PCT/JP2024/034244, filed Sep. 25, 2024, the international application being based upon and claiming the benefit of priority from Japanese Patent Application No. 2023-169435, filed on Sep. 29, 2023, the entire contents of each are incorporated herein by reference.

### TECHNICAL FIELD

Exemplary embodiments of the present disclosure relate to an etching method and a plasma processing apparatus.

### BACKGROUND

In the manufacture of electronic devices, plasma etching may be performed on a film on a substrate to form recesses in the film. Patent Document 1 discloses a plasma processing apparatus used for plasma etching, in which an electric bias for attracting ions into a substrate is applied to a substrate support. In the plasma processing apparatus described in Patent Document 1, a pulsed wave of consecutive pulsed voltages is disclosed as an example of the electric bias.

### Prior Art Documents

### PATENT DOCUMENTS

Patent Document 1: International Publication No. 2022/234643

### SUMMARY

In an exemplary embodiment, there is provided an etching method. The etching method includes: (a) providing a substrate, which includes a stacked film including a silicon oxide film and a silicon nitride film; (b) etching the silicon nitride film, while applying a first bias voltage to a substrate support configured to support the substrate, by using a first plasma generated from a first processing gas including a hydrofluorocarbon gas; and (c) etching the silicon oxide film, while applying a second bias voltage to the substrate support, by using a second plasma generated from a second processing gas including a fluorocarbon gas, an absolute value of a voltage value of the second bias voltage being larger than an absolute value of a voltage value of the first bias voltage, wherein each of the first bias voltage and the second bias voltage is a pulsed wave in which on and off states of a pulse of a DC voltage are repeated periodically, and an on-time of the pulse is 0.5 microseconds or less.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram schematically illustrating a plasma processing apparatus according to an exemplary embodiment of the present disclosure.

FIG. 2 is a diagram schematically illustrating a plasma processing apparatus according to an exemplary embodiment of the present disclosure.

FIG. 3 is a flowchart of an etching method according to an exemplary embodiment of the present disclosure.

FIG. 4 is a cross-sectional view of an example of a substrate to which the method of FIG. 3 may be applied.

FIG. 5 is a cross-sectional view illustrating one step of an etching method according to an exemplary embodiment of the present disclosure.

FIG. 6 is a cross-sectional view illustrating another step of an etching method according to an exemplary embodiment of the present disclosure.

FIG. 7 is an example of a timing chart illustrating a time change in source power and bias voltage.

FIG. 8 is an enlarged view of a part of the timing chart of FIG. 7.

FIG. 9A is a diagram illustrating an example of a first bias voltage and a substrate potential when an on-time exceeds 0.5 microseconds. FIG. 9B is a diagram illustrating an example of the first bias voltage and the substrate potential when the on-time is equal to or less than 0.5 microseconds.

FIG. 10 is a diagram illustrating experimental results of etching performed by an etching method according to an exemplary embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, various exemplary embodiments will be described in detail with reference to the drawings. In addition, the same reference numerals will be given to the same or corresponding parts in each drawing.

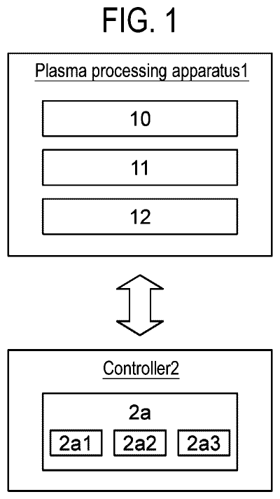

FIG. 1 is a diagram schematically illustrating a plasma processing apparatus according to an exemplary embodiment of the present disclosure. In an embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port configured to supply at least one processing gas into the plasma processing space, and at least one gas discharge port configured to discharge the gas from the plasma processing space. The gas supply port is connected to a gas supplier 20 to be described later, and the gas discharge port is connected to an exhaust system 40 to be described later. The substrate support 11 is arranged inside the plasma processing space and has a substrate support surface to support a substrate.

The plasma generator 12 is configured to generate a plasma from at least one processing gas supplied into the plasma processing space. The plasma generated in the plasma processing space may be a capacitively coupled plasma (CCP), inductively coupled plasma (ICP), electron-cyclotron-resonance (ECR) plasma, helicon wave excitation plasma (HWP), or surface wave plasma (SWP), or the like. Further, various types of plasma generators, including an alternating current (AC) plasma generator and a direct current (DC) plasma generator, may be used. In an embodiment, an AC signal (AC power) used in the AC plasma generator has a frequency within a range of 100 kHz to 10 GHz. Therefore, the AC signal includes a radio frequency (RF) signal and a microwave signal. In an embodiment, the RF signal has a frequency within a range of 100 kHz to 150 MHz.

The controller 2 processes computer-executable instructions that cause the plasma processing apparatus 1 to execute various steps described in the present disclosure. The controller 2 may be configured to control each component of the plasma processing apparatus 1 so as to execute various steps described herein. In an embodiment, a part or all of the controller 2 may be included in the plasma processing apparatus 1. The controller 2 may include a processor 2al, a storage 2a2, and a communication interface 2a3. The controller 2 is realized, for example, by a computer 2a. The processor 2al may be configured to perform various control operations by reading a program from the storage 2a2 and executing the read program. The program may be stored in advance in the storage 2a2, or may be acquired via a medium when necessary. The acquired program is stored in the storage 2a2 and is read from the storage 2a2 to be executed by the processor 2al. The medium may be any of various storage media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

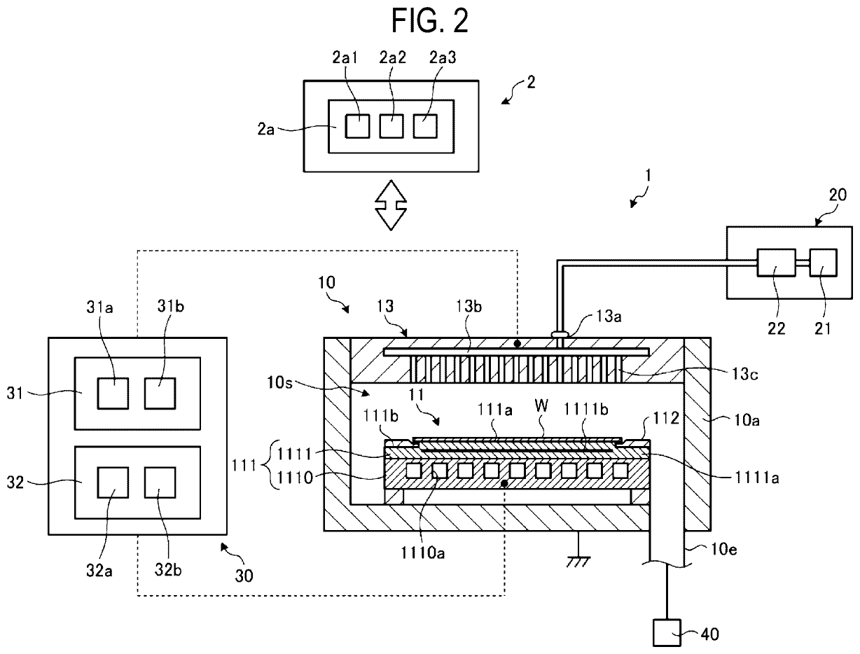

Hereinafter, a configuration example of a capacitively coupled plasma processing apparatus, as an example of the plasma processing apparatus 1, will be described. FIG. 2 is a diagram schematically illustrating the plasma processing apparatus according to an exemplary embodiment.

The capacitively coupled plasma processing apparatus 1 includes the plasma processing chamber 10, the gas supplier 20, a power supply 30, and the exhaust system 40. Further, the plasma processing apparatus 1 includes the substrate support 11 and a gas introducer. The gas introducer is configured to introduce at least one processing gas into the plasma processing chamber 10. The gas introducer includes a shower head 13. The substrate support 11 is arranged inside the plasma processing chamber 10. The shower head 13 is located above the substrate support 11. In an embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. Both the shower head 13 and the substrate support 11 are electrically insulated from a housing of the plasma processing chamber 10.

The substrate support 11 includes a main body 111 and a ring assembly 112. The main body 111 has a central region 111a to support a substrate W and an annular region 111b to support the ring assembly 112. A wafer is an example of the substrate W. The annular region 111b of the main body 111 surrounds the central region 111a of the main body 111, when viewed in a plan view. The substrate W is disposed on the central region 111a of the main body 111, and the ring assembly 112 is disposed on the annular region 111b of the main body 111 to surround the substrate W on the central region 111a of the main body 111. Therefore, the central region 111a is also referred to as a substrate support surface to support the substrate W, and the annular region 111b is also referred to as a ring support surface to support the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b embedded within the ceramic member 1111a. The ceramic member 1111a has the central region 111a. In an embodiment, the ceramic member 1111a also has the annular region 111b. In addition, another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode, which is coupled to an RF power supply 31, a DC power supply 32, or both of them to be described later, may be arranged within the ceramic member 1111a. In this case, at least one RF/DC electrode functions as a lower electrode. When a bias RF signal, a DC signal, or both to be described later is supplied to at least one RF/DC electrode, the RF/DC electrode is also referred to as a bias electrode. In addition, the conductive member of the base 1110 and at least one RF/DC electrode may function as a plurality of lower electrodes. Further, the electrostatic electrode 1111b may function as a lower electrode. Therefore, the substrate support 11 includes at least one lower electrode.

The ring assembly 112 includes one or multiple annular members. In an embodiment, one or multiple annular members include one or multiple edge rings and at least one cover ring. The edge ring is formed of a conductive material or an insulating material, and the cover ring is formed of an insulating material.

Further, the substrate support 11 may include a temperature regulation module configured to regulate at least one selected from a group of the electrostatic chuck 1111, the ring assembly 112, and the substrate to a target temperature. The temperature regulation module may include a heater, a heat transfer medium, a flow path 1110a, or a combination thereof. A heat transfer fluid such as brine or gas flows through the flow path 1110a. In an embodiment, the flow path 1110a is formed within the base 1110, and one or multiple heaters are disposed within the ceramic member 1111a of the electrostatic chuck 1111. Further, the substrate support 11 may include a heat transfer gas supplier configured to supply a heat transfer gas to a gap between a rear surface of the substrate W and the central region 111a.

The shower head 13 is configured to introduce at least one processing gas from the gas supplier 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. In addition to the shower head 13, the gas introducer may further include one or multiple side gas injectors (SGI) installed at one or multiple openings formed at the sidewall 10a.

The gas supplier 20 may include at least one gas source 21 and at least one flow rate controller 22. In an embodiment, the gas supplier 20 is configured to supply at least one processing gas from each corresponding gas source 21 to the shower head 13 through each corresponding flow rate controller 22. Each flow rate controller 22 may include, for example, a mass flow controller or a pressure-controlled flow rate controller. Further, the gas supplier 20 may include at least one flow rate modulation device configured to cause the flow rate of at least one processing gas to be modulated or pulsed.

The power supply 30 includes the RF power supply 31 coupled to the plasma processing chamber 10 via at least one impedance matching circuit. The RF power supply 31 is configured to supply at least one RF signal (RF power) to at least one lower electrode, at least one upper electrode, or both of them. This causes generation of plasma from the at least one processing gas supplied to the plasma processing space 10s. Therefore, the RF power supply 31 may function as at least a part of the plasma generator 12. Further, when a bias RF signal is supplied to at least one lower electrode, a bias potential occurs at the substrate W, enabling ion components of the generated plasma to be attracted into the substrate W.

In an embodiment, the RF power supply 31 includes a first RF generator 31a and a second RF generator 31b. The first RF generator 31a is coupled to at least one lower electrode, at least one upper electrode, or both of them via at least one impedance matching circuit, and is configured to generate a source RF signal (source RF power) for plasma generation. In an embodiment, the source RF signal has a frequency within a range of 10 MHz to 150 MHz. In an embodiment, the first RF generator 31a may be configured to generate multiple source RF signals with different frequencies. The generated one or multiple source RF signals are supplied to at least one lower electrode, at least one upper electrode, or both of them.

The second RF generator 31b is coupled to at least one lower electrode via at least one impedance matching circuit, and is configured to generate a bias RF signal (bias RF power). The frequency of the bias RF signal may be the same as or different from the frequency of the source RF signal. In an embodiment, the bias RF signal has a frequency lower than that of the source RF signal. In an embodiment, the bias RF signal has a frequency within a range of 100 kHz to 60 MHz. In an embodiment, the second RF generator 31b may be configured to generate multiple bias RF signals with different frequencies. The generated one or multiple bias RF signals are supplied to at least one lower electrode. Further, in various embodiments, at least one selected from a group of the source RF signal and the bias RF signal may be pulsed.

Further, the power supply 30 may include the DC power supply 32 coupled to the plasma processing chamber 10. The DC power supply 32 includes a first DC generator 32a and a second DC generator 32b. In an embodiment, the first DC generator 32a is connected to at least one lower electrode, and is configured to generate a first DC signal. The generated first DC signal is applied to at least one lower electrode. In an embodiment, the second DC generator 32b is connected to at least one upper electrode, and is configured to generate a second DC signal. The generated second DC signal is applied to at least one upper electrode.

In various embodiments, the first and second DC signals may be pulsed. In this case, a sequence of voltage pulses is applied to at least one lower electrode, at least one upper electrode, or both of them. The voltage pulses may have a rectangular, trapezoidal, or triangular pulse waveform, or a combination thereof. In an embodiment, a waveform generator configured to generate a sequence of voltage pulses from the DC signals is connected between the first DC generator 32a and at least one lower electrode. Therefore, the first DC generator 32a and the waveform generator constitute a voltage pulse generator. When the second DC generator 32b and the waveform generator constitute the voltage pulse generator, the voltage pulse generator is connected to at least one upper electrode. The voltage pulses may have a positive polarity or a negative polarity. Further, the sequence of voltage pulses may include one or multiple positive-polarity voltage pulses or one or multiple negative-polarity voltage pulses within one cycle. In addition, the first and second DC generators 32a and 32b may be installed in addition to the RF power supply 31, and the first DC generator 32a may be installed in place of the second RF generator 31b.

The exhaust system 40 may be connected, for example, to a gas discharge port 10e installed at a bottom of the plasma processing chamber 10. The exhaust system 40 may include a pressure adjustment valve and a vacuum pump. An internal pressure of the plasma processing space 10s is adjusted by the pressure adjustment valve. The vacuum pump may include a turbomolecular pump, a dry pump, or a combination thereof.

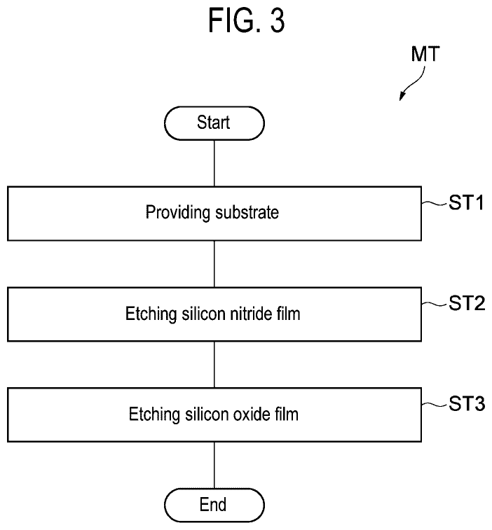

FIG. 3 is a flowchart of an etching method according to an exemplary embodiment. The etching method MT illustrated in FIG. 3 (hereinafter, referred to as “method MT”) may be executed by the plasma processing apparatus 1 of the above embodiment. The method MT may be applied to the substrate W.

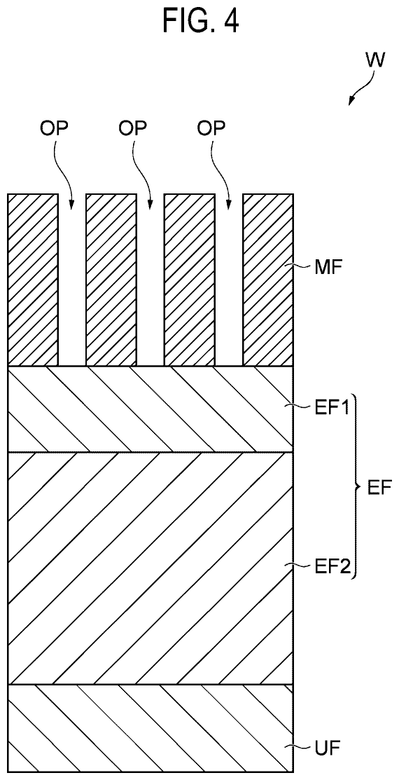

FIG. 4 is a cross-sectional view of an example of the substrate W to which the method MT may be applied. The substrate W illustrated in FIG. 4 may be used in the manufacture of semiconductor devices. The semiconductor devices may include, for example, memory devices such as DRAM and 3D-NAND, and logic devices. The substrate W includes a silicon-containing film EF. The substrate W may further include an underlying film UF. The silicon-containing film EF may be provided on the underlying film UF. The underlying film UF may include a material different from a material contained in the silicon-containing film EF. The underlying film UF may contain silicon.

The silicon-containing film EF includes a stacked film including a silicon oxide film (SiOₓ) EF2 and a silicon nitride film (SiNₓ) EF1. Herein, “x” is a positive real number. In the example of FIG. 4, the silicon oxide film EF2 is provided on the underlying film UF. The silicon nitride film EF1 is provided on the silicon oxide film EF2. A thickness of the silicon nitride film EF1 may be the same as or different from a thickness of the silicon oxide film EF2. When the thicknesses are different, the thickness of the silicon nitride film EF1 may be greater or smaller than the thickness of the silicon oxide film EF2.

In an example of FIG. 4, the silicon-containing film EF has a two-layer structure including the silicon oxide film EF2 and the silicon nitride film EF1. The silicon-containing film EF may also be, for example, a multilayer film including one or more silicon oxide films and one or more silicon nitride films, which are alternately stacked. The silicon-containing film EF may be, for example, a multilayer film including multiple silicon oxide films and multiple silicon nitride films, which are alternately stacked.

The substrate W may further include a mask MF having an opening OP. The opening OP may have a hole pattern or a line pattern. The mask MF may be provided on the silicon-containing film EF. The mask MF may include at least one selected from a group of a carbon-containing film and a metal-containing film. The carbon-containing film may include an amorphous carbon film. The metal-containing film may include at least one metal selected from a group of tungsten (W), titanium (Ti), and ruthenium (Ru).

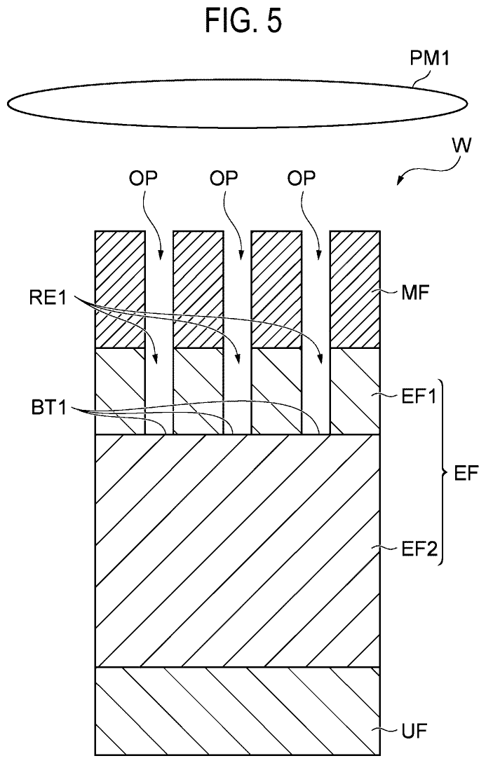

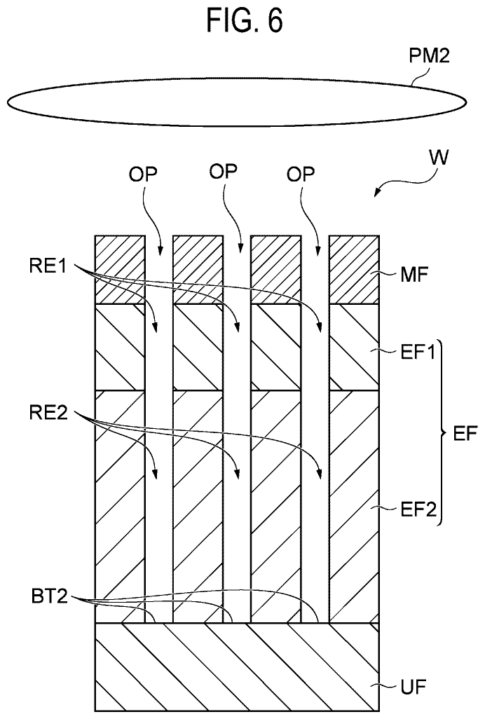

Hereinafter, the method MT will be described with reference to FIGS. 3 to 8, taking as an example the case where the method MT is applied to the substrate W by using the plasma processing apparatus 1 of the above embodiment. FIGS. 5 and 6 are cross-sectional views each illustrating one step of the etching method according to one exemplary embodiment. When the plasma processing apparatus 1 is used, the method MT may be executed in the plasma processing apparatus 1 by controlling each component of the plasma processing apparatus 1 with the controller 2. In the method MT, as illustrated in FIG. 2, the substrate W on the substrate support 11 arranged inside the plasma processing chamber 10 is processed.

As illustrated in FIG. 3, the method MT may include steps ST1, ST2 and, ST3. Steps ST1, ST2, and ST3 may be executed sequentially. After step ST3, steps ST2 and ST3 may be repeated.

### (Step ST1)

In step ST1, the substrate W illustrated in FIG. 4 is provided. The substrate W may be supported by the substrate support 11 inside the plasma processing chamber 10.

### (Step ST2)

In step ST2, a first plasma PM1 is generated from a first processing gas, and the silicon nitride film EF1 is etched by using the first plasma PM1. As illustrated in FIG. 5, a recess RE1 is formed in the silicon nitride film EF1 by etching. The recess RE1 corresponds to the opening OP. An upper surface of the silicon oxide film EF2 may be exposed at a bottom BT1 of the recess RE1. That is, the etching of the silicon nitride film EF1 may be performed until the bottom BT1 of the recess RE1 reaches the silicon oxide film EF2.

The first processing gas includes a hydrofluorocarbon gas (CₓH_{y}F_{z} gas). Each of x, y, and z is a natural number. The hydrofluorocarbon gas may be at least one selected from a group of CHF₃ gas, CH₂F₂ gas, CH₃F gas, C₂HF₄ gas, C₂H₂F₄ gas, C₂H₃F₃ gas, C₂H₄F₂ gas, C₃HF₇ gas, C₃H₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₆ gas, C₅H₂F₁₀ gas, and C₅H₃F₇ gas. The first processing gas may further include a fluorocarbon gas (CₓF_{y} gas). Each of x and y is a natural number. The fluorocarbon gas may be at least one selected from a group of C₄F₆ gas and C₄F₈ gas. The first processing gas may further include a nitrogen trifluoride gas (NF₃ gas). The first processing gas may further include an oxygen gas (O₂ gas).

In step ST2, the temperature of the substrate support 11 that supports the substrate W may be, for example, 50 degrees C. The temperature of the substrate support 11 may be set to 100 degrees C. or less, 80 degrees C. or less, or 60 degrees C. or less.

In step ST2, the internal pressure of the plasma processing chamber 10 may be, for example, 10 mTorr (1.3 Pa). The internal pressure of the plasma processing chamber 10 may be set to 50 mTorr (6.5 Pa) or less, or 30 mTorr (3.9 Pa) or less.

### (Step ST3)

In step ST3, a second plasma PM2 is generated from a second processing gas, and the silicon oxide film EF2 is etched by using the second plasma PM2. As illustrated in FIG. 6, a recess RE2 is formed in the silicon oxide film EF2 by etching. The recess RE2 corresponds to the recess RE1. The recess RE2 may be formed continuously from the recess RE1. An upper surface of the underlying film UF may be exposed at a bottom BT2 of the recess RE2. That is, the etching of the silicon oxide film EF2 may be performed until the bottom BT2 of the recess RE2 reaches the underlying film UF.

The second processing gas includes a fluorocarbon gas (CₓF_{y} gas). The fluorocarbon gas may be at least one selected from a group of C₂F₂ gas, C₂F₄ gas, C₃F₆ gas, C₃F₈ gas, C₄F₆ gas, C₄F₈ gas, and C₅F₈ gas. The second processing gas may further include a hydrofluorocarbon gas (CₓH_{y}F_{z} gas). An example of the CₓH_{y}F_{z} gas included in the second processing gas may be the same as the example of the CₓH_{y}F_{z} gas included in the first processing gas. The second processing gas may further include a nitrogen trifluoride gas. The second processing gas may further include an oxygen gas.

In step ST3, the temperature of the substrate support 11 that supports the substrate W may be, for example, 70 degrees C. The temperature of the substrate support 11 may be set to 100 degrees C. or less, or 80 degrees C. or less.

In step ST3, the internal pressure of the plasma processing chamber 10 may be, for example, 10 mTorr (1.3 Pa). The internal pressure of the plasma processing chamber 10 may be set to 50 mTorr (6.5 Pa) or less, or 30 mTorr (3.9 Pa) or less.

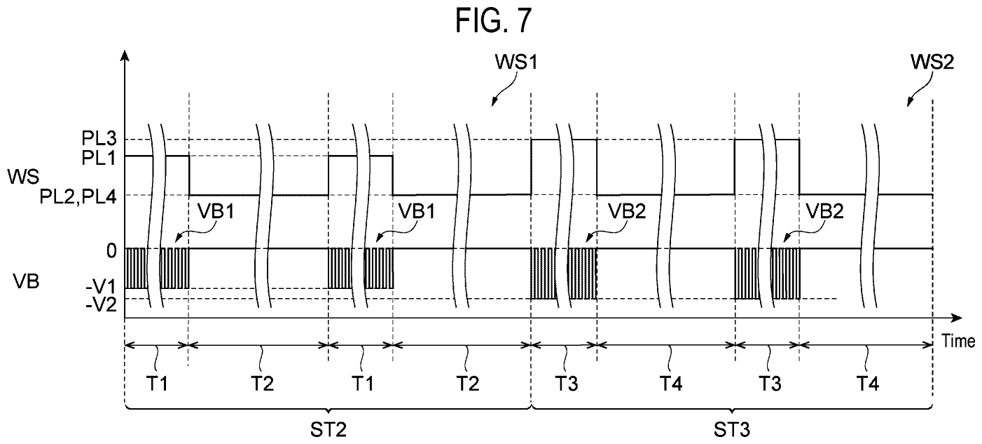

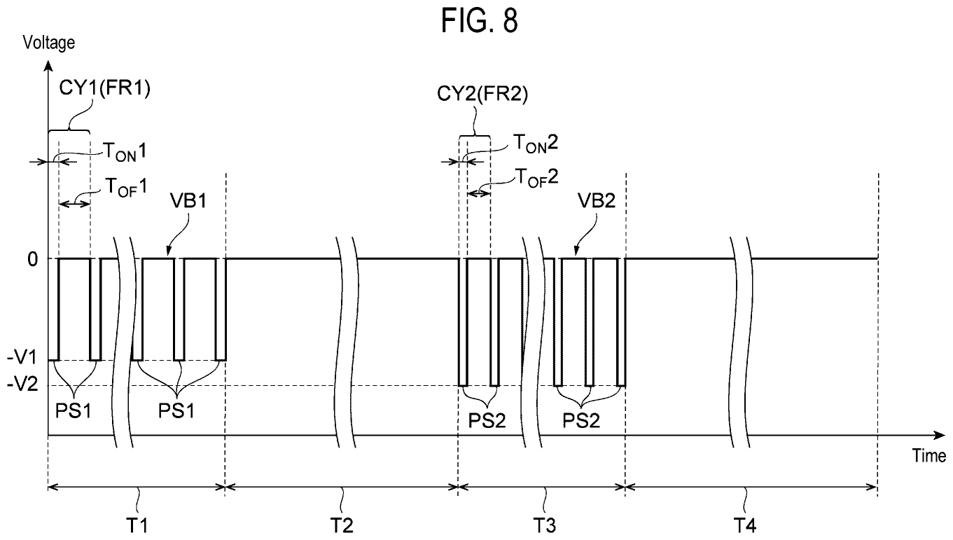

Next, the source RF power (hereinafter, also referred to as “source power”) and bias voltage supplied to the plasma processing apparatus 1 in steps ST2 and ST3 will be described with reference to FIGS. 7 and 8. The source power may be generated by the first RF generator 31a and be supplied to at least one lower electrode, at least one upper electrode, or both of them.

The bias voltage may be generated by the voltage pulse generator and be supplied to the substrate support 11. FIG. 7 is an example of a timing chart illustrating a time change in source power WS and bias voltage VB. A horizontal axis of FIG. 7 represents time. A vertical axis of FIG. 7 represents magnitudes of the source power WS and bias voltage VB. In other words, the vertical axis of FIG. 7 represents a power level (effective power value) of the source power WS and a value of the bias voltage VB.

The source power WS includes a first source power WS1 supplied in step ST2 and a second source power WS2 supplied in step ST3. The first source power WS1 may include a first power level PL1 and a second power level PL2, which is lower than the first power level PL1. The first power level PL1 and the second power level PL2 may be repeated periodically. The second power level PL2 may correspond to an off state (0 W) of the first source power WS1. While the first source power WS1 is at the first power level PL1, the first source power WS1 may promote the generation of the first plasma PM1. While the first source power WS1 is at the second power level PL2, the generation of the first plasma PM1 may be stopped, or a plasma having a lower plasma density than the first plasma PM1 may be generated.

The second source power WS2 may include a third power level PL3 and a fourth power level PL4, which is lower than the third power level PL3. The third power level PL3 and the fourth power level PL4 may be repeated periodically. The third power level PL3 may be higher than the first power level PL1. The fourth power level PL4 may correspond to an off state (0 W) of the second source power WS2. The fourth power level PL4 may be the same as or different from the second power level PL2. In the example of FIG. 7, the fourth power level PL4 is the same as the second power level PL2. While the second source power WS2 is at the third power level PL3, the second source power WS2 may promote the generation of the second plasma PM2. While the second source power WS2 is at the fourth power level PL4, the generation of the second plasma PM2 may be stopped, or a plasma having a lower plasma density than the second plasma PM2 may be generated.

The bias voltage VB includes a first bias voltage VB1 applied to the substrate support 11 in step ST2 and a second bias voltage VB2 applied to the substrate support 11 in step ST3. In step ST2, a first period T1 and a second period T2, which follows the first period T1, are periodically repeated. During the first period T1, The first bias voltage VB1 is applied. The first bias voltage VB1 may be a negative voltage. The application of the first bias voltage VB1 may cause ions contained in the first plasma PM1 to be attracted to the bottom BT1 of the recess RE1 formed in the silicon nitride film EF1, thereby proceeding the etching of the silicon nitride film EF1. On the other hand, during the second period T2, the first bias voltage VB1 is not applied. Thus, the etching of the silicon nitride film EF1 may be prevented during the second period T2.

In step ST3, a third period T3 and a fourth period T4, which follows the third period T3, are periodically repeated. In the present embodiment, the third period T3 follows the second period T2 in step ST2. During the third period T3, the second bias voltage VB2 is applied. The second bias voltage VB2 may be a negative voltage. The application of the second bias voltage VB2 may cause ions contained in the second plasma PM2 to be attracted to the bottom BT2 of the recess RE2 formed in the silicon oxide film EF2, thereby proceeding the etching of the silicon oxide film EF2. On the other hand, during the fourth period T4, the second bias voltage VB2 is not applied. Thus, the etching of the silicon oxide film EF2 may be prevented during the fourth period T4.

As illustrated in FIG. 7, in step ST2, the first source power WS1 may have the first power level PL1 during the first period T1. That is, the period during which the first source power WS1 has the first power level PL1 may be synchronized with the period during which the first bias voltage VB1 is applied in the first period T1. In this case, during the first period T1, the generation of the first plasma PM1 is promoted, such that the etching of the silicon nitride film EF1 may be promoted. In step ST2, the first source power WS1 may have the second power level PL2 during the second period T2. That is, the period during which the first source power WS1 has the second power level PL2 may be synchronized with the period during which the first bias voltage VB1 is not applied in the second period T2. In this case, during the second period T2, the generation of the second plasma PM2 is stopped or the plasma density is reduced, such that the etching of the silicon nitride film EF1 may be prevented.

As illustrated in FIG. 7, in step ST3, the second source power WS2 may have the third power level PL3 during the third period T3. That is, the period during which the second source power WS2 has the third power level PL3 may be synchronized with the period during which the second bias voltage VB2 is applied in the third period T3. In this case, during the third period T3, the generation of the second plasma PM2 is promoted, such that the etching of the silicon oxide film EF2 may be promoted. In step ST2, the second source power WS2 may have the fourth power level PL4 during the fourth period T4. That is, the period during which the second source power WS2 has the fourth power level PL4 may be synchronized with the period during which the second bias voltage VB2 is not applied in the fourth period T4. In this case, during the fourth period T4, the generation of the second plasma PM2 is stopped or the plasma density is reduced, such that the etching of the silicon oxide film EF2 may be prevented.

Next, the first bias voltage VB1 and the second bias voltage VB2 will be described in more detail with reference to FIG. 8. FIG. 8 is an enlarged view of a part of the timing chart of FIG. 7. The horizontal axis of FIG. 8 represents time. The vertical axis of FIG. 8 represents the voltage value. The first bias voltage VB1 is a pulsed wave in which on and off states of a pulse PS1 of a DC voltage are repeated periodically. In the present embodiment, the first bias voltage VB1 is a negative voltage, such that the pulse PS1 has a negative first DC voltage value (−V1) during an on-time T_{ON}1 and a voltage value of 0 V during an off-time T_{OF}1. The second bias voltage VB2 is a pulsed wave in which on and off states of a pulse PS2 of a DC voltage are repeated periodically. In the present embodiment, the second bias voltage VB2 is a negative voltage, such that the pulse PS2 has a negative second DC voltage value (−V2) during an on-time T_{ON}2 and a voltage value of 0 V during an off-time T_{OF}2.

An absolute value V2 of the second DC voltage value (−V2), which is the voltage value of the second bias voltage VB2, is greater than an absolute value (V1) of the first DC voltage value (−V1), which is the voltage value of the first bias voltage VB1. The absolute value (V1) of the first DC voltage value (−V1) may range from 1 kV to 5 kV. The absolute value (V2) of the second DC voltage value (−V2) may range from 5 kV to 20 kV.

A frequency FR2, which defines a cycle CY2 of the pulse PS2 of the second bias voltage VB2, may be higher than a frequency FR1, which defines a cycle CY1 of the pulse PS1 of the first bias voltage VB1. Alternatively, the frequency FR2, which defines the cycle CY2 of the pulse PS2 of the second bias voltage VB2, may be equal to or higher than the frequency FR1, which defines the cycle CY1 of the pulse PS1 of the first bias voltage VB1. Herein, the cycle CY1 is a total period of the on-time T_{ON}1 and the off-time T_{OF}1. Similarly, the cycle CY2 is a total period of the on-time TO_{N}2 and the off-time T_{OF}2. The frequency FR1 may range from 200 kHz to 400 kHz, or from 300 kHz to 500 kHz. The frequency FR2 may range from 200 kHz to 500 kHz, or from 300 kHz to 600 kHz.

The on-time T_{ON}1 of the pulse PS1 of the first bias voltage VB1 may be equal to the on-time TO_{N}2 of the pulse PS2 of the second bias voltage VB2. Each of the on-time T_{ON}1 and the on-time TO_{N}2 may be 0.5 microseconds (s) or less, 0.4 microseconds or less, or 0.2 microseconds or more. As described above, in a case where the frequency FR2 is higher than the frequency FR1, the on-time T_{ON}1 and the on-time T_{ON}2 are equal to each other, such that the off-time T_{OF}1 of the pulse PS1 is longer than the off-time T_{OF}2 of the pulse PS2.

A duty ratio of each of the first bias voltage VB1 and the second bias voltage VB2 may be 5% or more, 10% or more, 25% or less, or 20% or less. Herein, the duty ratio of the first bias voltage VB1 is a value expressed as a percentage of a ratio of the on-time T_{ON}1 to the cycle CY1. Herein, the duty ratio of the second bias voltage VB2 is a value expressed as a percentage of a ratio of the on-time T_{ON}2 to the cycle CY2.

The on-time T_{ON}1 starts simultaneously with a timing at which the power supply 30 of the plasma processing apparatus 1 starts outputting the first bias voltage VB1, and ends simultaneously with a timing at which the power supply 30 stops outputting the first bias voltage VB1 Due to an impedance or the like of a wiring path from the voltage pulse generator to the substrate support 11, the first bias voltage VB1 supplied to the substrate support 11 may reach a peak voltage value after a certain time has passed from the start of the on-time T_{ON}1. Similarly, the on-time TO_{N}2 starts simultaneously with a timing at which the power supply 30 of the plasma processing apparatus 1 starts outputting the second bias voltage VB2, and ends simultaneously with a timing at which the power supply 30 stops outputting the second bias voltage VB2 Due to the impedance or the like of the wiring path from the voltage pulse generator to the substrate support 11, the second bias voltage VB2 supplied to the substrate support 11 may reach a peak voltage value after a certain time has passed from the start of the on-time TO_{N}2.

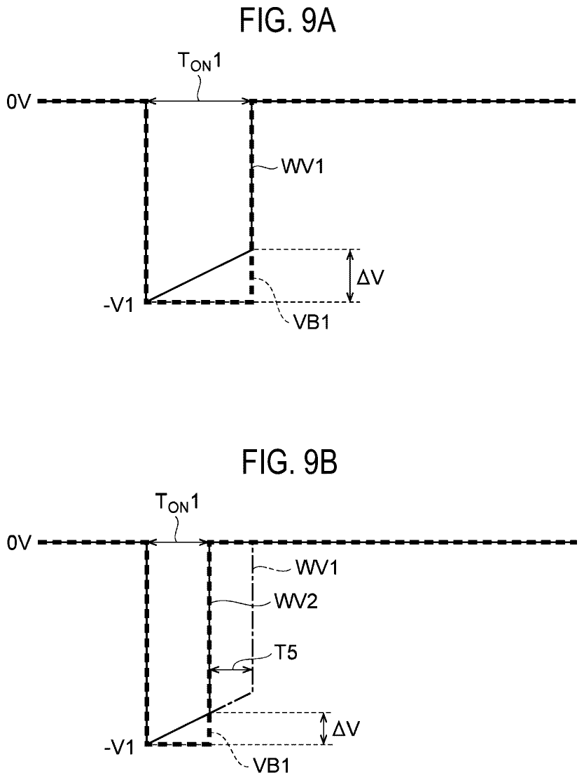

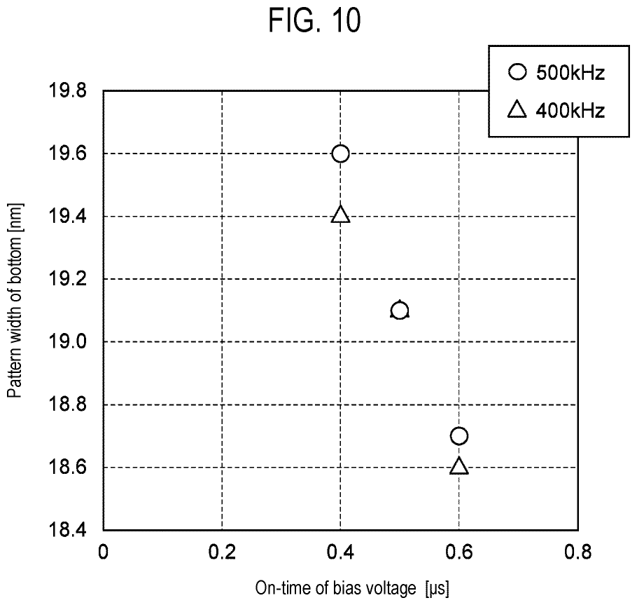

Next, effects of having short on-times T_{ON}1 and TO_{N}2 of 0.5 microseconds or less will be described with reference to FIGS. 9A to 10. In addition, the effects described herein are merely examples and are not limited thereto. FIG. 9A is a diagram illustrating an example of the first bias voltage VB1 and a potential WV1 of the substrate W when the on-time T_{ON}1 exceeds 0.5 microseconds. FIG. 9B is a diagram illustrating an example of the first bias voltage VB1 and a potential WV2 of the substrate W when the on-time T_{ON}1 is 0.5 microseconds or less. In addition, although FIGS. 9A and 9B illustrate the on-time T_{ON}1 of the first bias voltage VB1 as an example, the description of FIGS. 9A and 9B also applies to the on-time TO_{N}2 of the second bias voltage VB2.

As illustrated in FIGS. 9A and 9B, during the on-time T_{ON}1, the potentials WV1 and WV2 first reach the first DC voltage value (−V1) and then gradually change toward 0 V. Specifically, the potentials WV1 and WV2 of the substrate W change such that the absolute values of the potentials WV1 and WV2 of the substrate W decrease. When the first bias voltage VB1 switches from the on-time T_{ON}1 to the off-time T_{OF}1, the potentials WV1 and WV2 of the substrate W change steeply toward 0 V. The change amount ΔV of the potential WV2 illustrated in FIG. 9B is smaller than a change amount ΔV of the potential WV1 illustrated in FIG. 9A. The change amount ΔV of the potential WV1 is, for example, within 10% of the absolute value of the first DC voltage value (−V1). The change amount ΔV of the potential WV2 is, for example, within 5% of the absolute value of the first DC voltage value (−V1). As the change amount ΔV becomes smaller, the absolute value of the potential of the substrate W is easily maintained at a larger value. This makes it easier to attract ions contained in the first plasma PM1 into the bottom BT1 of the recess RE1, which is formed in the silicon nitride film EF1 by etching. As a result, a reduction in a pattern width at the bottom BT1 of the recess RE1 may be prevented. Similarly, a reduction in a pattern width at the bottom BT2 of the recess RE2, which is formed in the silicon oxide film EF2 by etching, may also be prevented.

As illustrated in FIG. 9B, a period T5 during which a change amount of the potential WV2 of the substrate W from the first DC voltage value (−V1) is large is excluded. Since the absolute value of the potential is smaller than the absolute value of the first DC voltage value (−V1) during the period T5, ions contained in the first plasma PM1 are unlikely to reach the bottom BT1, and are likely to collide with the top of the recess RE1. When the on-time T_{ON}1 is 0.5 microseconds or less, it becomes easier to prevent such ion collision with the top, making it easier to prevent widening of the pattern width at the top of the recess RE1. In this way, when the on-time T_{ON}1 is 0.5 microseconds or less, not only a reduction in the pattern width at the bottom BT1 of the recess RE1 but also the widening of the pattern width at the top of the recess RE1 may be prevented. This may eliminate shape abnormality of the recess RE1. Similarly, shape abnormality of the recess RE2 may also be eliminated.

As illustrated in FIG. 8, the frequency FR2, which defines the cycle CY2 of the pulse PS2 of the second bias voltage VB2, may be higher than the frequency FR1, which defines the cycle CY1 of the pulse PS1 of the first bias voltage VB1. Furthermore, the on-time T_{ON}1 of the pulse PS1 of the first bias voltage VB1 may be equal to the on-time T_{ON}2 of the pulse PS2 of the second bias voltage VB2. In this case, the off-time T_{OF} of the pulse PS1 of the first bias voltage VB1 will be longer than the off-time T_{OF}2 of the pulse PS2 of the second bias voltage VB2. During the off-times T_{OF}1 and T_{OF}2 of the pulses PS1 and PS2, ion attraction into the silicon oxide film EF2 or the silicon nitride film EF1 is prevented, and deposits tend to adhere to the sidewalls of the recesses RE1 and RE2. Therefore, when the off-time T_{OF}1 is longer than the off-time T_{OF}2, it is easier to protect the sidewalls in the etching of the silicon nitride film EF1, compared to the etching of the silicon oxide film EF2.

While various exemplary embodiments have been described above, various additions, omissions, substitutions, and modifications may be made without being limited to the exemplary embodiments described above. In the silicon-containing film EF, the silicon nitride film EF1 may be provided on the underlying film UF, and the silicon oxide film EF2 may be provided on the silicon nitride film EF1. In the method MT, step ST3 may be executed before step ST2. In this case, after step ST1, the third period T3 and the fourth period T4, which follows the third period T3, may be periodically repeated in step ST3. After that, in step ST2, the first period T1 may follow the last fourth period T4 in step ST3. In step ST2, the first period T1 and the second period T2, which follows the first period T1, may be periodically repeated.

Hereinafter, an experiment conducted to evaluate the method MT will be described. The following experiment is not intended to limit the present disclosure.

FIG. 10 is a diagram illustrating experimental results of etching performed by an etching method according to an exemplary embodiment. In the experiment, a substrate is prepared, which included a silicon oxide film as an etching target film, and a mask on the silicon oxide film. The mask includes a hole pattern opening. After the substrate is loaded into a plasma processing chamber, a plasma generated from a processing gas containing a fluorocarbon gas is used to etch an etching target film while applying a bias voltage to a substrate support. The bias voltage is a pulsed wave in which on and off states of a pulse of a DC voltage pulse are repeated periodically. The bias voltage is set to a voltage value of 7 kV. A frequency that defines a cycle of the pulse of the bias voltage is set to 400 kHz or 500 kHz. An on-time of the pulse of the bias voltage is changed between 0.4 microseconds and 0.6 microseconds for each frequency. After etching, a pattern width (critical dimension (CD)) at a bottom of a recess formed in the silicon oxide film is measured in a cross section of the substrate. Further, a pattern width at a top of the recess (a pattern width of the recess at an interface between the silicon oxide film and the mask) is measured.

As illustrated in FIG. 10, at a frequency of 500 kHz, the pattern width at the bottom when the on-time of the pulse is 0.5 microseconds is about 2.1% wider than the pattern width at the bottom when the on-time of the pulse is 0.6 microseconds. At the frequency of 500 kHz, the pattern width at the bottom when the on-time of the pulse is 0.4 microseconds is about 2.5% wider than the pattern width at the bottom when the on-time of the pulse is 0.5 microseconds. At a frequency of 400 kHz, the pattern width of the bottom when the on-time of the pulse is 0.5 microseconds is about 2.1% wider than the pattern width of the bottom when the on-time of the pulse is 0.6 microseconds. The pattern width at the bottom when the on-time of the pulse is 0.4 microseconds is about 1.5% wider than the pattern width at the bottom when the on-time of the pulse is 0.5 microseconds. From the results described above, it is found that the pattern width at the bottom of the recess formed in the silicon oxide film increases when the on-time of the pulse of the bias voltage decreases. Further, in all frequencies and on-times, the pattern width at the top of the recess is approximately 25.5 nm. Thus, it is found that the widening of the pattern width at the top of the recess may be prevented even when the on-time of the pulse of the bias voltage decreases.

Herein, various exemplary embodiments included in the present disclosure are described in the following [E1] to [E11].

[E1] An etching method including:
(a) providing a substrate, which includes a stacked film including a silicon oxide film and a silicon nitride film;
(b) etching the silicon nitride film, while applying a first bias voltage to a substrate support configured to support the substrate, by using a first plasma generated from a first processing gas including a hydrofluorocarbon gas; and
(c) etching the silicon oxide film, while applying a second bias voltage to the substrate support, by using a second plasma generated from a second processing gas including a fluorocarbon gas, an absolute value of a voltage value of the second bias voltage being larger than an absolute value of a voltage value of the first bias voltage,
wherein each of the first bias voltage and the second bias voltage is a pulsed wave in which on and off states of a pulse of a DC voltage are repeated periodically, and an on-time of the pulse is 0.5 microseconds or less.

[E2] The etching method of [E1], wherein a duty ratio of each of the first bias voltage and the second bias voltage is 20% or less.

[E3] The etching method of [E1] or [E2], wherein the duty ratio of each of the first bias voltage and the second bias voltage is 5% or more.

[E4] The etching method of any one of [E1] to [E3], wherein a frequency that defines a cycle of the pulse of the second bias voltage is equal to or higher than a frequency that defines a cycle of the pulse of the first bias voltage.

[E5] The etching method of any one of [E1] to [E3], wherein a frequency that defines a cycle of the pulse of the second bias voltage is higher than a frequency that defines a cycle of the pulse of the first bias voltage.

[E6] The etching method of [E5], wherein the on-time of the pulse of the first bias voltage is equal to the on-time of the pulse of the second bias voltage.

[E7] The etching method of any one of [E1] to [E6], wherein a frequency that defines a cycle of the pulse of the first bias voltage ranges from 200 kHz to 400 kHz, and
wherein a frequency that defines a cycle of the pulse of the second bias voltage ranges from 200 kHz to 500 kHz.

[E8] The etching method of any one of [E1] to [E7], wherein the absolute value of the voltage value of the first bias voltage ranges from 1 kV to 5 kV, and
wherein the absolute value of the voltage value of the second bias voltage ranges from 5 kV to 20 kV.

[E9] The etching method of any one of [E1] to [E8], wherein in (b), a first period and a second period that follows the first period are repeated periodically, and the first bias voltage is applied to the substrate support during the first period but is not applied during the second period, and
wherein in (c), a third period and a fourth period that follows the third period are repeated, and the second bias voltage is applied to the substrate support during the third period but is not applied during the fourth period.

[E10] The etching method of [E9], wherein in (b), a first source RF power is supplied to generate the first plasma,
wherein the first source RF power has a first power level and a second power level that is lower than the first power level, with the first power level and the second power level being repeated periodically,
wherein a period during which the first source RF power is at the first power level is synchronized with the first period during which the first bias voltage is applied,
wherein in (c), a second source RF power is supplied to generate the second plasma,
wherein the second source RF power has a third power level and a fourth power level that is lower than the third power level, with the third power level and the fourth power level being repeated periodically, and
wherein a period during which the second source RF power is at the third power level is synchronized with the third period during which the second bias voltage is applied.

[E11]A plasma processing apparatus including:
a chamber;
a substrate support configured to support a substrate inside the chamber, the substrate including a stacked film which includes a silicon oxide film and a silicon nitride film;
a gas supplier configured to supply a first processing gas including a hydrofluorocarbon gas and a second processing gas including a fluorocarbon gas into the chamber;
a plasma generator configured to generate a first plasma from the first processing gas and a second plasma from the second processing gas; and
a controller,
wherein the controller is configured to control the gas supplier and the plasma generator such that the silicon nitride film is etched by using the first plasma while applying a first bias voltage to the substrate support, and the silicon oxide film is etched by using the second plasma while applying a second bias voltage to the substrate support,
wherein an absolute value of a voltage value of the second bias voltage is larger than an absolute value of a voltage value of the first bias voltage, and
wherein each of the first bias voltage and the second bias voltage is a pulsed wave in which on and off states of a pulse of a DC voltage are repeated periodically, and an on-time of the pulse is 0.5 microseconds or less.

According to one exemplary embodiment, it is possible to eliminate the shape abnormality of a recess formed by etching.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An etching method comprising:
(a) providing a substrate, comprising a stacked film including a silicon oxide film and a silicon nitride film;
(b) etching the silicon nitride film, while applying a first bias voltage to a substrate support configured to support the substrate, by using a first plasma generated from a first processing gas including a hydrofluorocarbon gas; and
(c) etching the silicon oxide film, while applying a second bias voltage to the substrate support, by using a second plasma generated from a second processing gas including a fluorocarbon gas,
wherein an absolute value of a voltage value of the second bias voltage is larger than an absolute value of a voltage value of the first bias voltage,
wherein each of the first bias voltage and the second bias voltage is a pulsed wave in which on and off states of a pulse of a DC voltage are repeated periodically, and an on-time of the pulse is 0.5 microseconds or less.

2. The etching method of claim 1, wherein a duty ratio of each of the first bias voltage and the second bias voltage is 20% or less.

3. The etching method of claim 2, wherein the duty ratio of each of the first bias voltage and the second bias voltage is 5% or more.

4. The etching method of claim 1, wherein a duty ratio of each of the first bias voltage and the second bias voltage is 5% or more.

5. The etching method of claim 1, wherein a frequency that defines a cycle of the pulse of the second bias voltage is equal to or higher than a frequency that defines a cycle of the pulse of the first bias voltage.

6. The etching method of claim 1, wherein a frequency that defines a cycle of the pulse of the second bias voltage is higher than a frequency that defines a cycle of the pulse of the first bias voltage.

7. The etching method of claim 6, wherein the on-time of the pulse of the first bias voltage is equal to the on-time of the pulse of the second bias voltage.

8. The etching method of claim 1, wherein a frequency that defines a cycle of the pulse of the first bias voltage ranges from 200 kHz to 400 kHz, and
wherein a frequency that defines a cycle of the pulse of the second bias voltage ranges from 200 kHz to 500 kHz.

9. The etching method of claim 1, wherein the absolute value of the voltage value of the first bias voltage ranges from 1 kV to 5 kV, and
wherein the absolute value of the voltage value of the second bias voltage ranges from 5 kV to 20 kV.

10. The etching method of claim 1, wherein in (b), a first period and a second period that follows the first period are repeated periodically, and the first bias voltage is applied to the substrate support during the first period but is not applied during the second period, and
wherein in (c), a third period and a fourth period that follows the third period are repeated, and the second bias voltage is applied to the substrate support during the third period but is not applied during the fourth period.

11. The etching method of claim 10, wherein in (b), a first source RF power is supplied to generate the first plasma,
wherein the first source RF power has a first power level and a second power level that is lower than the first power level, with the first power level and the second power level being repeated periodically,
wherein a period during which the first source RF power is at the first power level is synchronized with the first period during which the first bias voltage is applied,
wherein in (c), a second source RF power is supplied to generate the second plasma,
wherein the second source RF power has a third power level and a fourth power level that is lower than the third power level, with the third power level and the fourth power level being repeated periodically, and
wherein a period during which the second source RF power is at the third power level is synchronized with the third period during which the second bias voltage is applied.

12. A plasma processing apparatus comprising:
a chamber;
a substrate support configured to support a substrate inside the chamber, the substrate comprising a stacked film which includes a silicon oxide film and a silicon nitride film;
a gas supplier configured to supply a first processing gas including a hydrofluorocarbon gas and a second processing gas including a fluorocarbon gas into the chamber;
a plasma generator configured to generate a first plasma from the first processing gas and a second plasma from the second processing gas; and
a controller,
wherein the controller is configured to control the gas supplier and the plasma generator such that the silicon nitride film is etched by using the first plasma while applying a first bias voltage to the substrate support, and the silicon oxide film is etched by using the second plasma while applying a second bias voltage to the substrate support,
wherein an absolute value of a voltage value of the second bias voltage is larger than an absolute value of a voltage value of the first bias voltage, and
wherein each of the first bias voltage and the second bias voltage is a pulsed wave in which on and off states of a pulse of a DC voltage are repeated periodically, and an on-time of the pulse is 0.5 microseconds or less.
